(19) United States
(12) Patent Application Publication
(10) Pub. No.: US 2026/0278465 A1
(43) Pub. Date: Sep. 17, 2026

(54) METHOD AND APPARATUS FOR TRAINING MODEL

(71) Applicant: Hon Hai Precision Industry Co., Ltd., New Taipei City (TW)

(72) Inventors: Tejender Singh Rawat, New Taipei City (TW); Chia-Lung HUNG, New Taipei City (TW); Wei-Cheng YU, New Taipei City (TW); Yi-Kai HSIAO, New Taipei City (TW); Surya Elangovan, New Taipei City (TW); Hao-Chung KUO, New Taipei City (TW)

(73) Assignee: Hon Hai Precision Industry Co., Ltd., New Taipei City (TW)

(21) Appl. No.: 19/561,517

(22) Filed: Mar. 10, 2026

Related U.S. Application Data
(60) Provisional application No. 63/769,753, filed on Mar. 11, 2025.

(51) Int. Cl. G06N 20/00

(52) U.S. Cl. CPC G06N 20/00

(57) ABSTRACT

A method and an apparatus for training a model of a semiconductor device are provided. In the method, a training environment including a dataset is established, where the dataset correlates a plurality of parameters of the semiconductor device with at least one electrical parameter. A state represented by a set of values of the parameters is defined in the training environment. An action is executed through a prediction model to modify at least one value in the set of values. A reward value is calculated based on a reward function, where the reward function is configured to guide the prediction model to maximize the electrical parameter, subject to a parameter constraint. A violation of the parameter constraint is penalized by a penalty that increases non-linearly with a degree of the violation. The prediction model is updated based on the reward value. Therefore, design efficiency and accuracy could be significantly enhanced.

### CROSS-REFERENCE TO RELATED APPLICATION

This application claims the priority benefit of provisional application Ser. No. 63/769,753, filed on Mar. 11, 2025. The entirety of the above-mentioned patent application is hereby incorporated by reference herein and made a part of this specification.

### BACKGROUND

### Technical Field

The present disclosure relates to semiconductor manufacturing, and more particularly, to a method and an apparatus for training a model of semiconductor device.

### Description of Related Art

In the design of high-voltage power semiconductor devices, such as the guard rings surrounding a Silicon Carbide (SiC) MOSFET, designers must define a multitude of structural and process parameters. These parameters typically include the number, width, and spacing of the guard rings, as well as the dose and energies for ion implantation. The precise combination of these parameters is critical for achieving a desired breakdown voltage and overall device performance.

Conventionally, the design process for these devices heavily relies on Technology Computer-Aided Design (TCAD) software for simulation and verification. This traditional workflow is fundamentally a “trial and error” methodology. A designer typically proposes an initial set of parameters, runs a TCAD simulation to evaluate the outcome, and then manually adjusts one or more parameters for the next simulation. This iterative process is repeated until the desired device characteristics are met.

However, this conventional approach suffers from significant drawbacks. A single TCAD simulation for a complex high-voltage device can be extraordinarily time-consuming, often requiring between 14 to 17 hours to complete for one set of parameters. Consequently, the reliance on numerous, sequential simulations dramatically extends the product development cycle and delays the time-to-market.

### SUMMARY

The present disclosure provides a method and an apparatus for training a model.

According to one or more exemplary embodiments of the present disclosure, a training method for a model, implemented by a processor, is provided. The method includes establishing a training environment comprising a dataset, where the dataset correlates semiconductor device parameters with at least one resultant electrical parameter. The semiconductor device parameters are for a Silicon Carbide (SiC) Trench Metal-Oxide-Semiconductor Field-Effect Transistor (MOSFET). The method further includes defining a state within the training environment, where the state is represented by a set of values for semiconductor device parameters. An action is executed through a prediction model to select or modify at least one value within the set of values representing the state. A reward value is then calculated based on a reward function. The reward function is configured to guide the prediction model to maximize a resultant electrical parameter of the semiconductor device, subject to a parameter constraint on the semiconductor device parameters. A violation of the parameter constraint is penalized by the reward function that increases non-linearly with a degree of the violation. The method includes updating the prediction model based on the reward value.

According to one or more exemplary embodiments of the present disclosure, an apparatus including a memory and a processor is provided. The memory is configured to store a program code. The processor is coupled to the memory. The processor is configured to load and execute the program code to perform: establishing a training environment comprising a dataset, where the dataset correlating semiconductor device parameters with at least one resultant electrical parameter, and the semiconductor device parameters are used by a semiconductor device for SiC Trench MOSFET; defining a state within the training environment, where the state is represented by a set of values for the semiconductor device parameters; executing an action through a prediction model to select or modify at least one value within the set of values representing the state; calculating a reward value based on a reward function, where the reward function is configured to guide the prediction model to maximize a resultant electrical parameter of the semiconductor device, subject to a parameter constraint on the semiconductor device parameters, and a violation of the parameter constraint is penalized by the reward function that increases non-linearly with a degree of the violation; and updating the prediction model based on the reward value.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a block diagram of an apparatus for training a model according to an exemplary embodiment of the present disclosure.

FIG. 2 is a flowchart of a training method for a model according to an exemplary embodiment of the present disclosure.

FIG. 3 is a schematic diagram illustrating a semiconductor device according to an exemplary embodiment of the present disclosure.

FIG. 4 is a schematic diagram illustrating a reward function according to an exemplary embodiment of the present disclosure.

FIG. 5 is a diagram illustrating a relationship between a breakdown voltage and an ion implantation dose for a semiconductor device according to an exemplary embodiment of the present disclosure.

FIG. 6 is a graph showing the learning progress of an RL agent according to a first exemplary embodiment of the present disclosure.

FIG. 7 is a graph showing the learning progress of an RL agent according to a second exemplary embodiment of the present disclosure.

FIG. 8 is a graph showing the learning progress of an RL agent according to a third exemplary embodiment of the present disclosure.

FIG. 9 is a graph showing the learning progress of an RL agent according to a fourth exemplary embodiment of the present disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

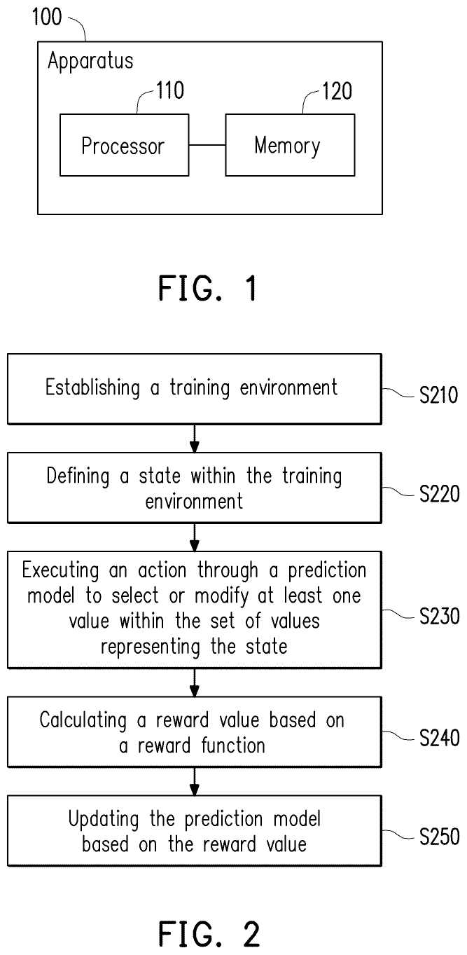

FIG. 1 is a block diagram of an apparatus 100 for training a model according to an exemplary embodiment of the present disclosure. Referring to FIG. 1, the apparatus 100 may be a personal computer, a workstation, a server, or any electronic device with computational capabilities. The apparatus 100 includes, but is not limited to, a memory 110 and a processor 120.

The memory 110 is coupled to the processor 120. In some embodiments, the memory 110 may be any type of fixed or removable random-access memory (RAM), read-only memory (ROM), flash memory, a hard disk drive (HDD), a solid-state drive (SSD), or other similar components or a combination of the foregoing. In one embodiment, the memory 110 is used to store data and program code. For example, the memory 110 stores program code for the training method, datasets generated from simulations, parameters for a prediction model, and configuration files.

The processor 120 is coupled to the memory 110. In some embodiments, the processor 120 may be a central processing unit (CPU), a graphics processing unit (GPU), a microprocessor, a digital signal processor (DSP), an application-specific integrated circuit (ASIC), a field-programmable gate array (FPGA), a neural network accelerator, or other similar programmable devices or a combination thereof. In one embodiment, the processor 120 is used to load and execute the program code and data stored in the memory 110 to perform the operations of the apparatus 100. For example, the processor 120 is configured to execute the training method described in the following exemplary embodiments.

To facilitate a clear understanding of the operational flow of the present disclosure, numerous embodiments will be detailed below to illustrate the working process. The methods described hereinafter will be explained in conjunction with the components of FIG. 1.

FIG. 2 is a flowchart of a training method for a model according to an exemplary embodiment of the present disclosure. Referring to FIG. 2, the training method is implemented by the processor 120.

In step S210, the processor 120 establishes a training environment. Specifically, the training environment is a virtual space configured for the prediction model or other machine learning models to learn, and the training environment includes a dataset. The dataset serves as the foundation for the learning process. The dataset correlates multiple semiconductor device parameters with one or more resultant electrical parameters. In practical applications, this dataset may be generated by running numerous device simulations using various software tools, such as, but not limited to, Technology Computer-Aided Design (TCAD) tools or other physics-based simulation platforms. Each entry in the dataset represents a specific simulated device, linking a unique combination of input parameters (e.g., the semiconductor device parameters) to a corresponding simulated output performance (e.g., resultant electrical parameters).

In one embodiment, the semiconductor device parameters include one or more structural parameters. The structural parameter is defined as a parameter that describes the physical geometry or layout of the semiconductor device. For example, structural parameters may include the space between guard rings (“s”), the width of the guard rings (“w”), and the number of guard rings (“GR”). For another example, structural parameters may include drift region doping concentration (“N_{d}”), drift region thickness (“t_{drift}”), oxide thickness (“tₒₓ”), and substrate thickness (“tₛ”).

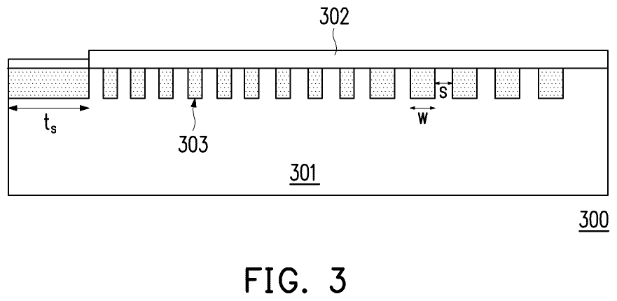

FIG. 3 is a schematic diagram illustrating a semiconductor device 300 according to an exemplary embodiment of the present disclosure. Referring to FIG. 3, the semiconductor device 300 is, for example, a Silicon Carbide (SiC) Trench Metal-Oxide-Semiconductor Field-Effect Transistor (MOSFET). The semiconductor device 300 includes a main transistor structure 301, for example, a Trench MOSFET, an oxide layer 302, and multiple guard rings 303. The main transistor structure 301 is, for example, a Trench MOSFET located in a central region of the semiconductor device 300. The main transistor structure 301 fundamentally includes a gate, a channel region, and the oxide layer 302. The oxide layer 302, typically a gate oxide, is a thin layer of insulating material (such as silicon dioxide) that electrically isolates the gate electrode from the semiconductor channel. The quality and thickness of this oxide layer 302 are critical parameters that directly influence the transistor's performance, including its threshold voltage and reliability. The guard rings 303 are structures arranged around the main transistor structure 301. The guard rings 303 help the semiconductor device 300 to withstand higher voltages, thereby enhancing its high-voltage capability. The semiconductor device parameters discussed in the present disclosure, such as the number, width, and spacing of the guard rings, directly correspond to the physical characteristics of these guard rings 302.

In one embodiment, the semiconductor device parameters include one or more process parameters. The process parameter is defined as a parameter related to the manufacturing or fabrication steps of the semiconductor device. For example, process parameters may include the ion implantation dose (“Dose”) and multiple ion implantation energies (for example, “energy_300”, “energy_600”, “energy_900”). The ion implantation energies determine the depth to which impurities are implanted into the semiconductor structure. A higher energy level results in a deeper implantation, while a lower energy level results in a shallower implantation closer to the surface of the semiconductor device. For example, the multiple ion implantation energies may be specified in kilo-electron volts (KeV) and may include distinct levels such as “energy_300”, “energy_600”, and “energy_900”, corresponding to implantations at 300 KeV, 600 KeV, and 900 KeV, respectively.

In one embodiment, the resultant electrical parameter is a performance metric obtained from the simulation. For example, the resultant electrical parameter may be the breakdown voltage (BV) of the semiconductor device.

In step S220, the processor 120 defines a state within the training environment. Specifically, a state represents a specific instance or a potential device design within the design space, and the state is represented by a set of values for the semiconductor device parameters. The prediction model observes the current state to determine a subsequent action to explore the design space. For example, a state may be represented by a set of parameter values such as {s: 1 μm, w: 1.5 μm, GR: 7, Dose: 5.7e+11, energy_300: 300 KeV, energy_600: 900 KeV, energy_900: 900 KeV}.

In step S230, the processor 120 executes an action through a prediction model to select or modify at least one value within the set of values representing the state. Specifically, an action is a decision made by the prediction model to alter the current state. By executing actions, the prediction model iteratively modifies the semiconductor device parameters, thereby exploring different design configurations to find combinations that lead to improved performance. For example, an action may be increasing the value of the “Dose” parameter by a specific percentage or changing the value of the “GR” parameter from one integer to another, such as from 9 to 10.

In step S240, the processor 120 calculates a reward value based on a reward function. Specifically, a reward value is a numerical score that provides feedback to the prediction model, indicating the quality of the state that resulted from the previous action. The reward function is the core logic that guides the learning process of the prediction model. The reward function is configured to guide the prediction model to maximize a resultant electrical parameter of the semiconductor device, subject to a parameter constraint. A violation of the parameter constraint is penalized by the reward function that increases non-linearly with a degree of the violation. This non-linear penalty is critical for efficiently guiding the prediction model to avoid undesirable regions of the design space. For example, the main objective may be maximizing the breakdown voltage (BV) (i.e., the resultant electrical parameter of the semiconductor device).

In one embodiment, the parameter constraint is a predetermined range for an ion implantation dose, and the ion implantation dose is one of the semiconductor device parameters. A parameter constraint may be applied to the “Dose” parameter (i.e., the parameter of ion implantation dose), requiring the value of the “Dose” parameter to be within an optimal range (i.e., the predetermined range, for example, between a minimum dose and a maximum dose).

In one embodiment, the processor 120 may determine the reward value according to the breakdown voltage in response to the parameter constraint being satisfied. When or only when the selected value of the “Dose” parameter is within the predetermined range, the reward value is determined based on the achieved breakdown voltage. For example, the reward value equals the value of the breakdown voltage. Then, the resultant electrical parameter of the semiconductor device would be improved (e.g., achieve a higher breakdown voltage) by the positive reward value.

In one embodiment, the processor 120 may apply a non-linear penalty to the reward value in response to the violation of the parameter constraint (e.g., the “Dose” parameter is located outside the predetermined range). Specifically, the penalty increases non-linearly with the degree of the violation. A non-linear penalty provides a stronger learning signal to the prediction model compared to a linear one, as it severely penalizes states that are far from the desired parameter range. For example, the non-linear penalty is proportional to a fourth power of the degree of the violation. When or only when the selected value of the “Dose” parameter violates this constraint, a penalty is applied. This penalty may be calculated non-linearly, for instance, as a function proportional to the fourth power of the absolute difference between the selected value of the “Dose” parameter and a median dose value. This non-linear approach ensures that large deviations from the optimal range are penalized severely, thus accelerating the learning process. The reward value is inversely proportional to the penalty. The reward value may be, for example, −(penalty*100).

In one embodiment, the processor 120 may calculate the degree of the violation based on a difference between a value of the ion implantation dose (dose) and a median value (median_dose) of the predetermined range (e.g., ((abs(dose−median_dose))\hat{ }4)). The median value may be, for example, (min_dose+max_dose)/2.

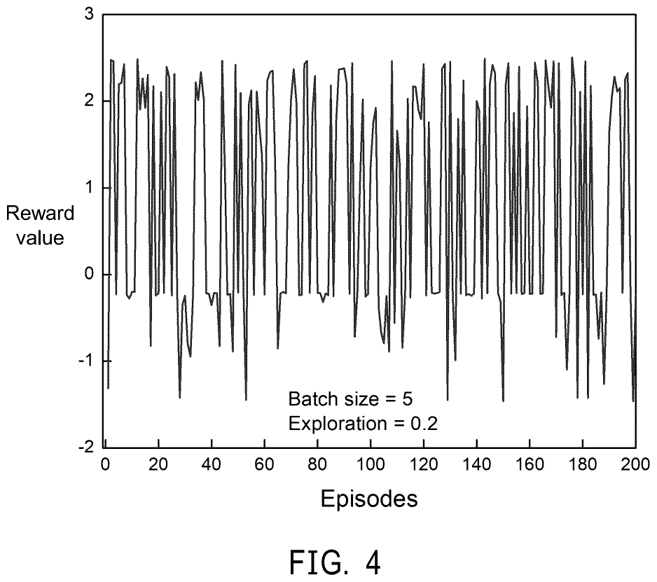

For example, FIG. 4 is a schematic diagram illustrating a reward function according to an exemplary embodiment of the present disclosure. Referring to FIG. 4, the reward function is the logic implemented by the processor 120 to calculate the reward value in step S240. The reward function operates based on whether the parameter constraint is satisfied. Specifically, a parameter constraint is defined for the ion implantation dose (“Dose”). The parameter constraint specifies a predetermined range defined by a minimum dose (min_dose) and a maximum dose (max_dose). The reward function 400 checks if the current value of the “Dose” parameter falls within this predetermined range. If the constraint is satisfied (i.e., the “Dose” parameter falls within the predetermined range), a reward branch is executed, where the reward value is determined from the corresponding resultant electrical parameter, for example, the breakdown voltage (BV). If the constraint is violated (i.e., the “Dose” parameter falls outside the predetermined range), a penalty branch is executed. In this branch, a penalty is calculated based on the degree of the violation, which may be the absolute difference between the current “Dose” value and a median dose value. The penalty is non-linear, for example, the penalty is proportional to the fourth power of this difference. The final reward value is then set to the negative of this calculated penalty.

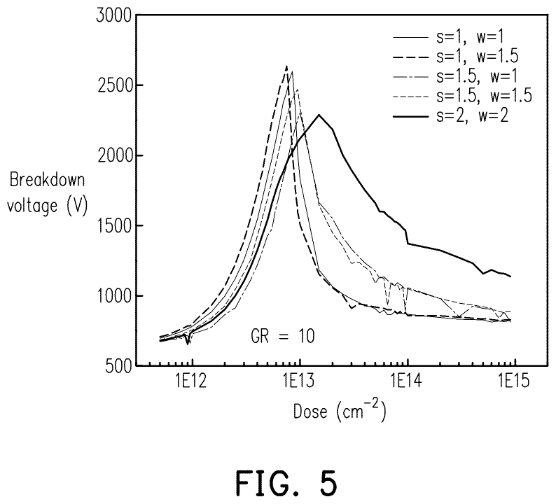

FIG. 5 is a diagram illustrating a relationship between a breakdown voltage and an ion implantation dose for a semiconductor device according to an exemplary embodiment of the present disclosure. Referring to FIG. 5, the diagram shows that for different structural parameters (for example, different combinations of space and width for the guard rings), the peak breakdown voltage is achieved at different optimal ion implantation dose values. A dose that is either too low or too high for a given structure results in a suboptimal breakdown voltage. This empirical relationship provides the technical basis and justification for establishing a parameter constraint on the ion implantation dose within the reward function, as described in FIG. 4. By defining a predetermined range for the implantation dose, the training process can be guided to focus on the most promising regions of the design space that are likely to yield high-performance devices.

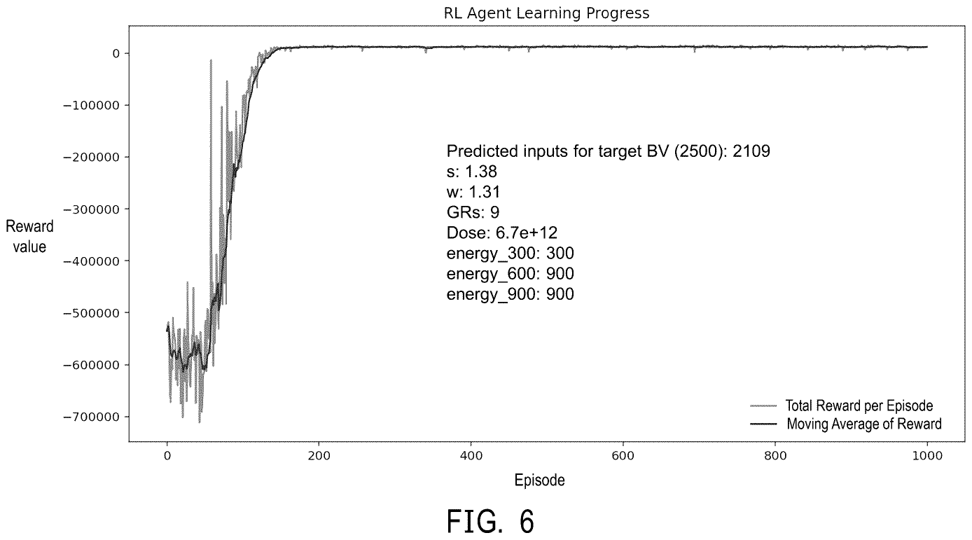

In step S250, the processor 120 updates the prediction model based on the reward value. Specifically, based on the feedback provided by the reward value, the prediction model adjusts its internal parameters (for example, weights in a neural network). The purpose of the update is to reinforce actions that lead to high rewards and suppress actions that lead to low penalties. In one embodiment, the prediction model is a reinforcement learning (RL) model. Through many iterations of this state-action-reward-update loop, the prediction model learns a policy that is effective at finding semiconductor device parameters that yield a high resultant electrical parameter while satisfying all parameter constraints. For example, the successful learning process is evidenced by the “RL Agent Learning Progress” graphs, as shown in FIGS. 6-9, where the total reward per episode consistently increases and stabilizes at a high reward value over the course of the training.

The following exemplary embodiments, illustrated in FIGS. 6-9, demonstrate the results of applying the training method. In these examples, the prediction model, which is a reinforcement learning (RL) model, is trained to predict semiconductor device parameters for a target breakdown voltage of 2500 V.

FIG. 6 is a graph showing the learning progress of an RL agent according to a first exemplary embodiment of the present disclosure. Referring to FIG. 6, the graph plots the total reward per episode and the moving average of the reward against the number of training episodes. The graph illustrates that after an initial period of exploration characterized by low and volatile rewards, the RL agent's performance rapidly improves and converges to a stable and high reward value at approximately 200 episodes. This convergence demonstrates the effectiveness of the training method and the non-linear reward function in guiding the model to learn an optimal policy. In this embodiment, after training, the prediction model was used to predict input parameters for the target breakdown voltage of 2500 V. The predicted input parameters were: a space (“s”) of 1.38, a width (“w”) of 1.31, 9 guard rings (“GR”), an ion implantation dose (“Dose”) of 6.7e+12, and implantation energies of 300 KeV, 900 KeV, and 900 KeV. A subsequent simulation using these predicted parameters yielded a breakdown voltage of 2109 V.

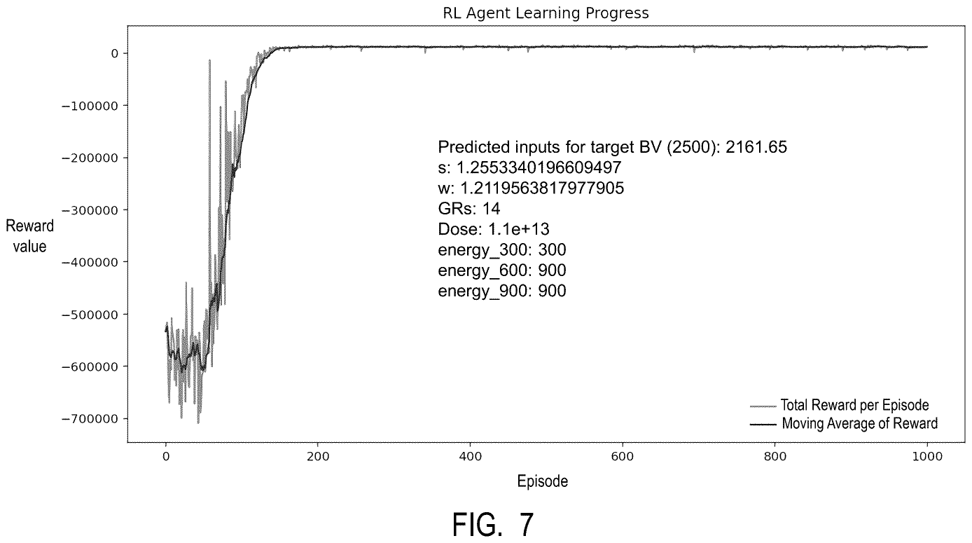

FIG. 7 is a graph showing the learning progress of an RL agent according to a second exemplary embodiment of the present disclosure. Referring to FIG. 7, the learning curve is similar to that of the first embodiment, showing a rapid convergence to a stable, high-reward state. This further validates the robustness of the training method across different training runs or minor variations in hyperparameters. In this embodiment, the trained prediction model predicted the following input parameters for the target breakdown voltage of 2500 V: a space (“s”) of approximately 1.26, a width (“w”) of approximately 1.21, 14 guard rings (“GR”), an ion implantation dose (“Dose”) of 1.1e+13, and implantation energies of 300 KeV, 900 KeV, and 900 KeV. A subsequent simulation using these predicted parameters resulted in a breakdown voltage of 2161.65 V.

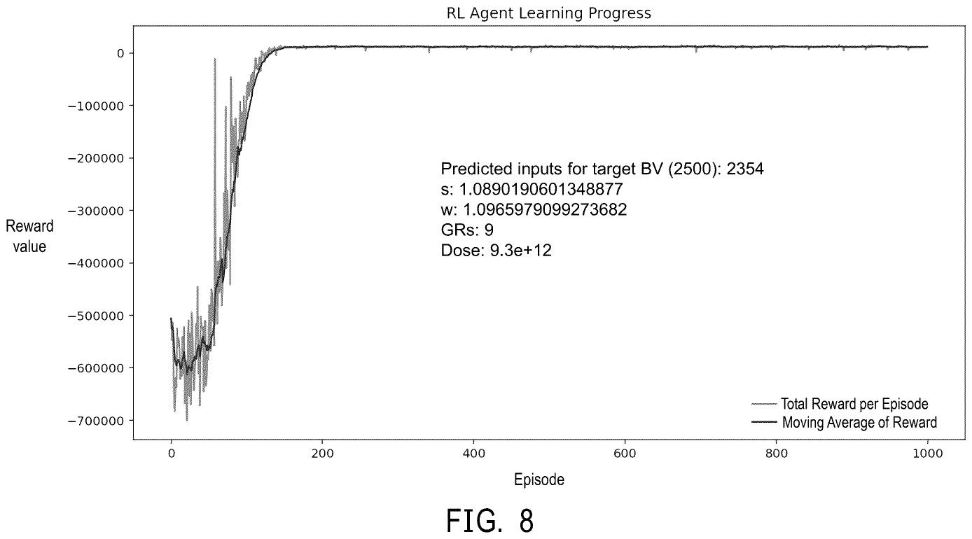

FIG. 8 is a graph showing the learning progress of an RL agent according to a third exemplary embodiment of the present disclosure. Referring to FIG. 8, the graph again demonstrates the successful learning and convergence of the RL agent. This embodiment illustrates that the method is effective even when predicting a different subset of parameters. In this embodiment, the prediction model was trained to predict parameters for the target breakdown voltage of 2500 V, excluding the specific energy levels. The predicted input parameters were: a space (“s”) of approximately 1.09, a width (“w”) of approximately 1.1 , 9 guard rings (“GR”), and an ion implantation dose (“Dose”) of 9.3e+12. It should be noticed that A subsequent simulation with these parameters resulted in a breakdown voltage of 2354 V. A subsequent simulation using these predicted parameters yielded a breakdown voltage of 2215 V.

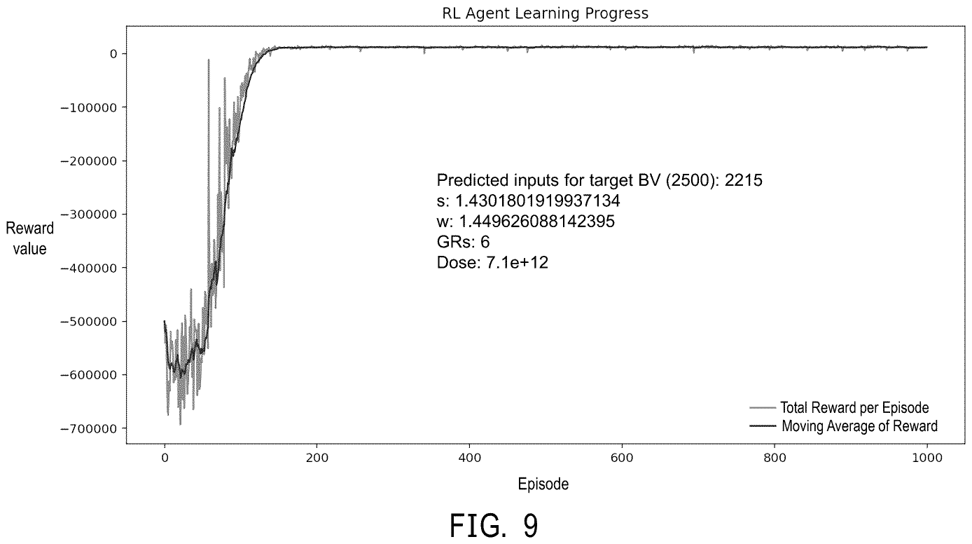

FIG. 9 is a graph showing the learning progress of an RL agent according to a fourth exemplary embodiment of the present disclosure. Referring to FIG. 9, the learning progress shown is consistent with the previous embodiments. In this fourth embodiment, for the same target breakdown voltage of 2500 V and also excluding energy levels, the trained model predicted a different set of viable input parameters: a space (“s”) of approximately 1.43, a width (“w”) of approximately 1.45, 6 guard rings (“GR”), and an ion implantation dose (“Dose”) of 7.1e+12. A subsequent simulation using these predicted parameters yielded a breakdown voltage of 2215 V. The ability to generate multiple, distinct, and high-performing parameter sets, as shown in the embodiments of FIGS. 6-9, is a significant advantage, providing designers with multiple viable options for device fabrication.

In one or more exemplary embodiments, the prediction model is implemented as a reinforcement learning (RL) model, such as a Proximal Policy Optimization (PPO) agent or an Advantage Actor-Critic (A2C) agent. The underlying neural network for the agent may comprise multiple hidden layers, for example, two hidden layers with 128 neurons each, using an activation function such as the hyperbolic tangent (tanh) function. The training process is governed by a set of hyperparameters, which may be configured to include a memory size of 20000, a batch size of 64, an exploration rate of 0.5, a learning rate of 1e−3, and a discount factor of 0.99.

After the training process described in FIG. 2 is complete, the updated prediction model can be utilized for performing an inverse prediction for a new semiconductor device. Specifically, the processor 120 may receive a target electrical parameter, such as a new target breakdown voltage, for the new semiconductor device. A user, such as a device designer, provides a single, high-level performance specification for a new semiconductor device that is to be designed. For example, the designer may input a target breakdown voltage of 2500 V for a new power application.

The processor 120 then utilizes the trained prediction model to determine a new semiconductor device parameters based on the received target electrical parameter. Specifically, the processor 120 takes the received target electrical parameter as the sole input to the trained prediction model. The prediction model, having learned the relationships between the parameters and the electrical performance during the training phase, performs an inverse prediction. This inverse prediction process does not involve iterative simulations; instead, the prediction model directly calculates and generates a complete set of multi-dimensional input parameters that, according to its learned policy, are predicted to achieve the specified target (e.g., the target electrical parameter).

Finally, the processor 120 outputs the new semiconductor device parameters, providing a complete and viable design specification that can be used for subsequent TCAD verification or manufacturing. Specifically, the processor 120 outputs the new semiconductor device parameters determined by the prediction model. This output constitutes a complete and viable design specification. For example, in response to the 2500 V target electrical parameter, the output could be the specific parameter set {s: 1.09, w: 1.10, GR: 9, Dose: 9.3e+12}. This output can then be used by the designer for a final verification simulation in a TCAD tool or as a direct baseline for the manufacturing process, thus replacing the time-consuming manual trial-and-error loop of the conventional design method.

In summary, the training method and apparatus of the present disclosure utilize a prediction model, particularly for example, a reinforcement learning model, guided by a non-linear reward function to solve the problem of semiconductor device parameter design. By performing an inverse prediction, the method directly generates a set of optimal input parameters based on a single target output specification. This approach fundamentally overcomes the limitations of the conventional trial-and-error methodology, which is inefficient and heavily reliant on engineering experience. The disclosed method significantly reduces the time and computational resources required for device design, accelerates the product development cycle, and improves the overall quality and reliability of the final design by systematically exploring the design space to find high-performing solutions.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A training method of model, implemented by a processor, and the training method comprising:
establishing a training environment comprising a dataset, wherein the dataset correlating a plurality of semiconductor device parameters with at least one resultant electrical parameter, and the plurality of semiconductor device parameters are used by a semiconductor device for silicon carbide (SiC) Trench metal-oxide-semiconductor field-effect transistor (MOSFET);
defining a state within the training environment, wherein the state is represented by a set of values for the plurality of semiconductor device parameters;
executing an action through a prediction model to select or modify at least one value within the set of values representing the state;
calculating a reward value based on a reward function, wherein the reward function is configured to guide the prediction model to maximize a resultant electrical parameter of the semiconductor device, subject to a parameter constraint on the plurality of semiconductor device parameters, and a violation of the parameter constraint is penalized by the reward function that increases non-linearly with a degree of the violation; and
updating the prediction model based on the reward value.

2. The training method of model according to claim 1, wherein the resultant electrical parameter of the semiconductor device is a breakdown voltage (BV).

3. The training method of model according to claim 1, wherein the parameter constraint is a predetermined range for an ion implantation dose, and the ion implantation dose is one of the plurality of semiconductor device parameters.

4. The training method of model according to claim 3, wherein calculating the reward value based on the reward function comprises:
calculating the degree of the violation based on a difference between a value of the ion implantation dose and a median value of the predetermined range.

5. The training method of model according to claim 1, wherein calculating the reward value based on the reward function comprises:
applying a non-linear penalty to the reward value in response to the violation of the parameter constraint, wherein the non-linear penalty is proportional to a fourth power of the degree of the violation.

6. The training method of model according to claim 1, wherein the plurality of semiconductor device parameters comprises at least one structural parameter selected from a group consisting of:
a space between a plurality of guard rings, a width of the plurality of guard rings, and a number of the plurality of guard rings.

7. The training method of model according to claim 1, wherein the plurality of semiconductor device parameters comprises at least one process parameter selected from a group consisting of: an ion implantation dose and a plurality of ion implantation energies.

8. The training method of model according to claim 2, wherein calculating the reward value based on the reward function comprises:
determining the reward value according to the breakdown voltage in response to the parameter constraint being satisfied.

9. The training method of model according to claim 1, wherein the prediction model is a reinforcement learning (RL) model.

10. The training method of model according to claim 1, wherein the prediction model is used to determine a plurality of new semiconductor device parameters for a new semiconductor device based on a target electrical parameter.

11. An apparatus related to training model, comprising:
a memory, used for storing a program code; and
a processor, coupled to the memory, configured to load and execute the program code to perform:
establishing a training environment comprising a dataset, wherein the dataset correlating a plurality of semiconductor device parameters with at least one resultant electrical parameter, and the plurality of semiconductor device parameters are used by a semiconductor device for silicon carbide (SiC) Trench metal-oxide-semiconductor field-effect transistor (MOSFET);
defining a state within the training environment, wherein the state is represented by a set of values for the plurality of semiconductor device parameters;
executing an action through a prediction model to select or modify at least one value within the set of values representing the state;
calculating a reward value based on a reward function, wherein the reward function is configured to guide the prediction model to maximize a resultant electrical parameter of the semiconductor device, subject to a parameter constraint on the plurality of semiconductor device parameters, and a violation of the parameter constraint is penalized by the reward function that increases non-linearly with a degree of the violation; and
updating the prediction model based on the reward value.

12. The apparatus related to training model according to claim 11, wherein the resultant electrical parameter of the semiconductor device is a breakdown voltage (BV).

13. The apparatus related to training model according to claim 11, wherein the parameter constraint is a predetermined range for an ion implantation dose, and the ion implantation dose is one of the plurality of semiconductor device parameters.

14. The apparatus related to training model according to claim 13, wherein the processor is further configured to perform:
calculating the degree of the violation based on a difference between a value of the ion implantation dose and a median value of the predetermined range.

15. The apparatus related to training model according to claim 11, wherein the processor is further configured to perform:
applying a non-linear penalty to the reward value in response to the violation of the parameter constraint, wherein the non-linear penalty is proportional to a fourth power of the degree of the violation.

16. The apparatus related to training model according to claim 11, wherein the plurality of semiconductor device parameters comprises at least one structural parameter selected from a group consisting of: a space between a plurality of guard rings, a width of the plurality of guard rings, and a number of the plurality of guard rings.

17. The apparatus related to training model according to claim 11, wherein the plurality of semiconductor device parameters comprises at least one process parameter selected from a group consisting of: an ion implantation dose and a plurality of ion implantation energies.

18. The apparatus related to training model according to claim 12, wherein the processor is further configured to perform:
determining the reward value according to the breakdown voltage in response to the parameter constraint being satisfied.

19. The apparatus related to training model according to claim 11, wherein the prediction model is a reinforcement learning (RL) model.

20. The apparatus related to training model according to claim 11, wherein the prediction model is used to determine a plurality of new semiconductor device parameters for a new semiconductor device based on a target electrical parameter.
